(19) United States
(12) Patent Application Publication
(10) Pub. No.: US 2007/0212802 A1
(43) Pub. Date: Sep. 13, 2007

(54) Method for manufacturing light emitting diode package

(75) Inventors: Hai Sung Lee, Suwon (KR); Jong Myeon Lee, Gwacheon (KR); Ho Sung Choo, Suwon (KR); Myung Whun Chang, Seoul (KR); Youn Gon Park, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/708,471

(22) Filed: Feb. 21, 2007

(30) Foreign Application Priority Data
Feb. 21, 2006 (KR) 10-2006-0016848

(51) Int. Cl. H01L 21/00

(52) U.S. Cl. 438/22

(57) ABSTRACT

A method of manufacturing an LED package with improved light extraction efficiency. A light-emitting resin part of an LED package is formed and laser beam is irradiated on a surface of the light-transmitting resin part of the LED package to roughen the surface thereof.

### CLAIM OF PRIORITY

This application claims the benefit of Korean Patent Application No. 2006-0016848 filed on Feb. 21, 2006, in the Korean Intellectual Property Office, the disclosure of which is incorporated herein by reference.

### BACKGROUND OF THE INVENTION

1. Field of the Invention

The present invention relates to a method of manufacturing a Light Emitting Diode (LED) package and, more particularly, to a method of manufacturing an LED package which can effectively improve light extraction efficiency.

2. Description of the Related Art

Recently, Light Emitting Diodes (hereinafter, LEDs) have gained importance in various applications as an environmentally friendly light source which does not cause pollution. For example, the LEDs are applied to traffic lights, instruction lamps, keypads of mobile phones and the like, and also have proven their potential use as a backlight for LCD apparatuses or light sources for illumination. Such LEDs are combined with various structures of substrates to be manufactured in packages.

In order to realize an LED product with high luminance and efficiency, not only the LED chip itself must have high internal quantum efficiency but also the photons generated at the chip must be efficiently extracted to the outside. Therefore, there have been suggested diverse remedies for improving the external light extraction efficiency of an LED package. The remedies include, for example, adjusting the refractive index of a resin encapsulant or using a hemispheric polymer lens. However, to realize a high-quality LED package, even higher light extraction efficiency is required. That is, it has been confirmed that adjusting the refractive index does not have a significant effect of improving the light extraction efficiency, especially in the case of a side view type LED package.

FIG. 1 is a side sectional view illustrating a conventional LED package. Referring to FIG. 1, the LED package 10 includes a package body 11 with a reflecting cup formed in an upper part thereof and an LED chip 15 mounted in the reflecting cup of the package body 11. The LED chip 15 is electrically connected to lead frames 13 installed on a floor surface of the reflecting cup and is encapsulated by a light-transmitting resin encapsulant 17 of a silicone resin, etc. The resin encapsulant 17 has phosphor dispersed therein to convert the wavelengths, allowing generation of a wavelength of light different from that of the light originally emitted from the LED chip 15. If necessary, a lens may be mounted on the resin encapsulant 17.

The light is generated from the LED chip 15, passes through the resin encapsulant 17, and extracted into the external air. Thus, to achieve higher light extraction efficiency, the light should effectively exit the resin encapsulant into the external air. However, as the refractive index n1 of the resin encapsulant 17 is greater than the refractive index n2 of the external air, the light incident onto the surface of the resin encapsulant 17 in angles greater than the critical angle is totally reflected, not extracted out of the package and becomes extinct inside the package. In the case where a lens (not shown) is formed on the resin encapsulant 17, the above described condition takes place between the lens and the external air.

Thus, in order to improve the light extraction efficiency at the surface of the resin encapsulant or the lens, there has been suggested a method of forming a rough pattern on the surface of the resin encapsulant or the lens by using a mold, a stamper or by etching (refer to Japanese Laid-Open Publication Application 2005-251875). However, this method is not suitable for the LED package (see FIG. 1) with a reflecting cup formed therein and renders it difficult to regulate the process of forming the rough pattern. Especially, it is difficult and costly to fabricate a mold with an elaborate rough pattern. Further, in the process of pressing the resin encapsulant into a stamper having a rough pattern or etching a stamper, the resin encapsulant can be greatly damaged, degrading the optical characteristics.

### SUMMARY OF THE INVENTION

The present invention has been made to solve the foregoing problems of the prior art and therefore an aspect of the present invention is to provide a method of manufacturing a Light Emitting Diode (LED) package which can increase light extraction efficiency at a surface of a light-transmitting resin part such as a resin encapsulant or a lens.

Another aspect of the invention is to provide a method of manufacturing an LED package which can easily roughen a surface of the light-transmitting resin part in various forms while preventing deterioration of the light-transmitting resin part.

According to an aspect of the invention, the invention provides a method of manufacturing a light emitting diode package. The method includes:
forming a light-transmitting resin part of a light emitting diode package; and
irradiating a laser beam on a surface of the light transmitting resin part to roughen the surface of the light-transmitting resin part.

According to an embodiment of the present invention, the light-transmitting resin part can be a resin encapsulant for encapsulating an LED chip. In this case, the step of forming the light-transmitting resin part includes encapsulating the LED chip with the resin encapsulant and curing the resin encapsulant. According to an embodiment of the present invention, the resin encapsulant may be made of a silicone resin.

In addition, the resin encapsulant may be made of one selected from the group consisting of polyethylene, polypropylene, polystyrene, polyethylene terephthalate, polyethylene terenaphthalate, polybutylene terephthalate, polyethersulfone, polyetheretherketone, polycarbonate, polyimide, polyetherimide, a cellulose triacetate resin, a polyacrylate resin, a polysulfone resin and a fluoride resin.

According to another embodiment of the present invention, the step of forming a light-transmitting resin part includes forming a lens. In this case, the method may further include mounting the lens on the package body with the LED chip mounted therein between the step of forming a light-transmitting resin part and the step of irradiating a laser beam. Alternatively, the method may further include mounting the lens on the package body with the LED chip mounted therein after the step of irradiating the laser beam. According to an embodiment of the present invention, the lens may be made of a silicone resin or epoxy resin.

Preferably, the step of irradiating the laser beam includes placing a cover plate, which transmits the laser beam, on the light-transmitting resin part. Placing the cover plate prevents the material evaporated or spattered from the light-transmitting resin part by the laser irradiation from polluting the lens of a laser irradiator.

According to an embodiment of the present invention, the step of irradiating the laser beam may include placing a pattern mask, which selectively transmits the laser beam, on the light-transmitting resin part. Using such a pattern mask allows forming a regular rough pattern or a roughness on a surface of the light-transmitting resin part. For example, a pattern mask with a plurality of slits can be used to form a plurality of rough patterns in stripes on the surface of the light-transmitting resin part.

Preferably, the laser beam adopts a pulse laser beam, especially an excimer laser beam. The laser beam may adopt one selected from the group consisting of a KrF laser beam of a wavelength of 248 nm, an ArF laser beam of a wavelength of 193 nm, a CO₂ gas pulse laser beam and a Nd—YAG pulse laser beam of a wavelength of 355 nm.

According to an embodiment of the present invention, the light transmitting resin may be made of a silicone resin and the laser beam may adopt a KrF laser beam having an energy density of 500 to 1000 mJ/cm² and a repetition frequency of 100 Hz.

According to the present invention, a laser ablation process is used to roughen the surface of the light-transmitting resin part (the resin encapsulant or the resin lens of the LED package. A laser ablation refers to a process of irradiating a laser beam (typically a pulse laser beam) on an object to ablate the surface of the object. In case of irradiating a laser beam on a resin surface, the resin surface is melted to be evaporated or peeled off.

The roughened surface of the light-transmitting resin part by the laser beam irradiation functions to increase the light extraction efficiency into the external air. Furthermore, using the laser ablation, the energy density, the repetition frequency and laser duration can be adjusted to finely regulate the process and to prevent undesired damage to the transparent resin part.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view illustrating a conventional LED package;

FIG. 2 is a sectional view illustrating an LED package formed by a manufacturing method according to an embodiment of the present invention;

FIG. 3 is a sectional view illustrating an LED package formed by a manufacturing method according to another embodiment of the present invention;

FIG. 4 is a schematic view illustrating a laser ablation process performed on a surface of a resin encapsulant according to the manufacturing method of an embodiment of the present invention;

FIG. 5 is a schematic view illustrating a laser ablation process performed on a surface of a lens according to the manufacturing method of another embodiment of the present invention;

FIG. 6a is a schematic view illustrating a laser ablation process using a pattern mask according to the manufacturing method of an embodiment of the present invention;

FIG. 6b is a view illustrating a roughened surface of a light-transmitting resin part obtained by the laser ablation process shown in FIG. 6a;

FIG. 7 is a flowchart illustrating the manufacturing method according to an embodiment of the present invention;

FIG. 8 is a flowchart illustrating the manufacturing method according to another embodiment of the present invention;

FIG. 9 is a flowchart illustrating the manufacturing method according to further another embodiment of the present invention; and

FIG. 10 shows Atomic Force Microscope (AFM) images and Scanning Electronic Microscope (SEM) pictures taken on the surfaces of the resin encapsulants obtained respectively from Comparative and Inventive Examples.

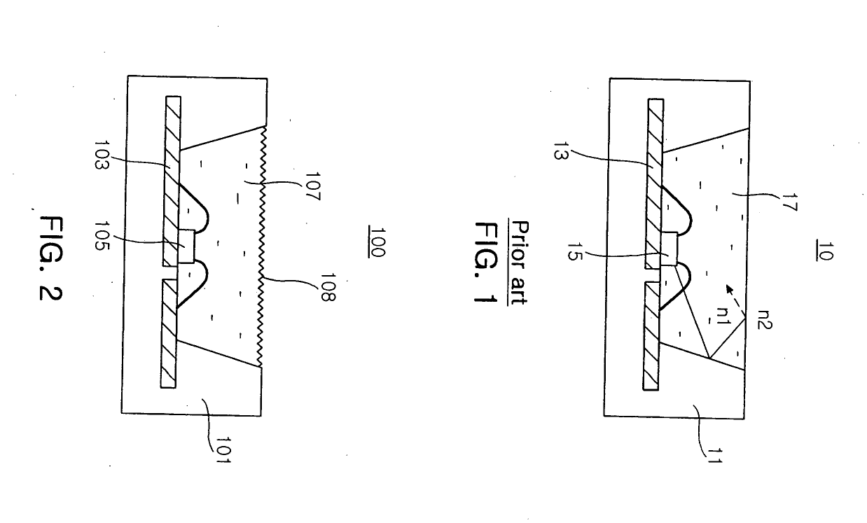

### DETAILED DESCRIPTION OF THE PREFERRED EMBODIMENT

Exemplary embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions are exaggerated for clarity, and the same reference numerals are used throughout to designate the same or similar components.

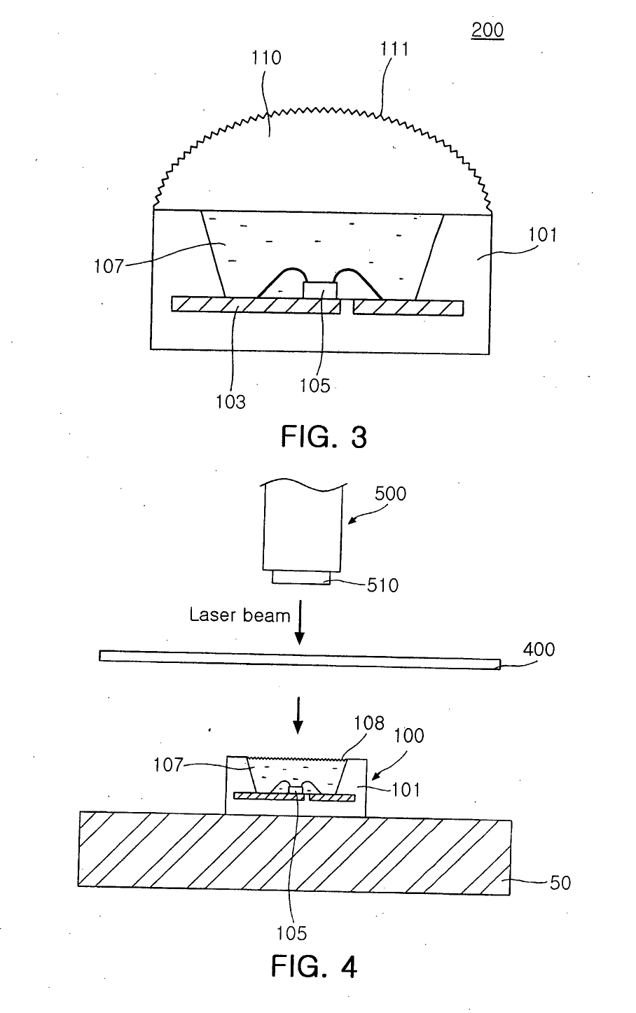

FIGS. 2 and 3 are sectional views illustrating LED packages manufactured by methods according to embodiments of the present invention. Referring to FIG. 2, the LED package 100 includes an LED package body 101 with lead frames 103 installed therein and an LED chip 105 mounted therein. The LED chip 105 is encapsulated by a resin encapsulant 107 made of a silicone resin, etc. As shown in FIG. 2, a surface of the resin encapsulant 107 is roughened by a laser ablation process to be described later.

Roughening the surface of the resin encapsulant by the laser ablation process can also be applied to a resin lens as well besides the resin encapsulant 107. Such an example is illustrated in FIG. 3. Referring to FIG. 3, the LED package 200 further includes a resin lens 110 mounted on the package body 101. The surface 111 of the lens 110 is roughened by the laser ablation process.

Roughening the surface of the resin encapsulant 107 or the surface of the resin lens 110 by the laser ablation process as just described allows significantly improved extraction efficiency of light into the external air and the overall light efficiency of the package.

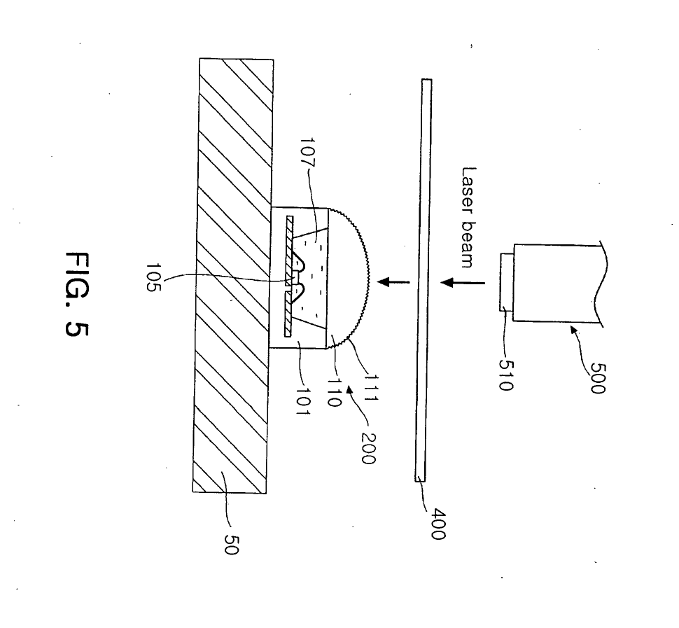

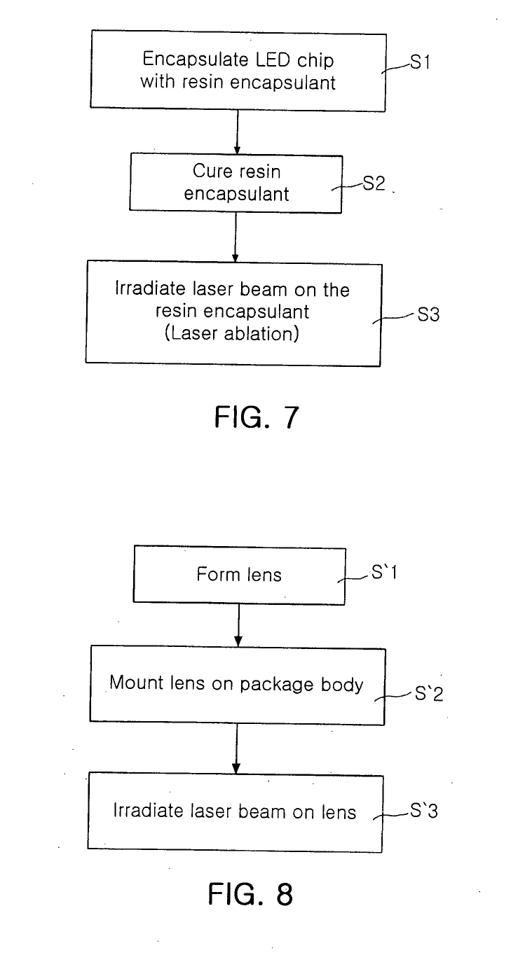

FIG. 4 is a schematic view illustrating the laser ablation process according to an embodiment of the present invention and FIG. 7 is a flowchart illustrating the manufacturing method of an LED package according to an embodiment of the present invention. The manufacturing method of an LED package will now be explained with reference to FIGS. 4 to 7.

First, the LED chip 105 is mounted and encapsulated by the resin encapsulant 107 (S1). For example, a silicone resin can be used for the resin encapsulant 107. Then, the resin encapsulant 107 encapsulating the LED chip 105 is cured (S2). Thereafter, as shown in FIG. 4, a surface of the resin encapsulant 107 is roughened using a laser ablation process (S3).

Referring to FIG. 4, the LED package 100 is fixed on a support substrate 50. A laser beam irradiator 500 installed above the package 100 irradiates a laser beam to the surface 108 of the resin encapsulant 107 to roughen the surface 108. By this laser beam irradiation, polymer is melted, peeled off, evaporated or left as residue on the surface of the resin encapsulant 107. Thereby, a texture or roughness is formed on the surface of the resin encapsulant 107. Using the laser ablation process allows no damage on the resin encapsulant 107, except for the surface 108.

Preferably, a cover plate 400 of a sapphire wafer capable of transmitting the laser beam is placed between the package 100 and the laser beam irradiator 500. Placing such a cover plate 400 can prevent the polymer evaporated or spattered from the resin encapsulant 107 from polluting the lens 510 of the laser irradiator 500.

The laser beam usable in the laser ablation process includes various kinds. Preferably, a pulse laser beam with a great energy density is used, among which an excimer laser beam in particular is used. For example, a KrF laser beam of a wavelength of 248 nm, an ArF laser beam of a wavelength of 193 nm, a CO₂ gas pulse laser beam and an Nd—YAG pulse laser beam of a wavelength of 355 nm can be used.

The process conditions adjustable during the laser beam irradiation include the energy density of the laser beam, pulse duration, repetition frequency, focused beam size and the like. These conditions can be adjusted to allow precise and easy regulation of the laser ablation process.

For the material of the resin encapsulant 107, a silicone-based polymer resin can be used. In addition, the resin encapsulant 107 can be made of one selected from the group consisting of polyethylene (PE), polypropylene (PP), polystyrene (PS), polyethylene terephthalate (PET), polyethylene terenaphthalate (PEN), polybutelene terephthalate (PBT), polyethersulfone (PES), polyetheretherketone (PEEK), polycarbonate (PC), polyimides (PI), polyetherimide, a cellulose triacetate resin, a polyacrylate resin, a polysulfone resin and a fluoride resin.

The extent of ablation by laser and the roughened form of the surface may vary according to the types of the polymer constituting the resin encapsulant 107. This is because, polymers have different steric hindrance in the form of chains and space charge and the strength of bonding between the monomers of the polymer varies. Therefore, even if the energy density of the laser beam irradiated on the resin encapsulant 107 is constant, the energy needed for dissolving the polymer differs for each polymer.

In a microscopic point of view, when the excimer laser beam is irradiated on the resin encapsulant 107, the energy of the photons of the laser beam is transferred to the monomers or the molecules inside the polymer. This transferred energy dissociates the chemical bonding inside the polymer, and thereby the polymer is sublimated or left as residue. Through this process, the surface of the resin encapsulant 107 is roughened. The important factors in a laser ablation process include energy density per unit area, pulse duration and time interval of the laser beam irradiation.

In particular, the most important condition is the energy density of the laser beam. Even if the same amount of total energy is transferred to the resin encapsulant 107, the ablation effect is greater when the laser beam is irradiated at a greater energy density for fewer number of times than when the laser beam is irradiated at a smaller energy density for many times. This is because threshold dissociation energy exists in the chemical bonding that forms the polymer. That is, in order to dissociate the chemical bonding in the resin encapsulant 107, energy of a predetermined intensity or higher should be exerted each time.

FIG. 5 is a schematic view illustrating a laser ablation process performed on a resin lens and FIG. 8 is a flowchart illustrating an example of manufacturing method of an LED package using the laser ablation process shown in FIG. 5. The manufacturing method of an LED package is explained as follows with reference to FIGS. 5 and 8.

First, the resin lens 110 (e.g. a lens made of silicone or epoxy resin) is formed by for example injection molding (S′1) and then, the lens 110 is mounted on the package body 101 with the LED chip 105 mounted therein (S′2). Thereafter, using the laser beam irradiator 500 as shown in FIG. 5, the laser beam is irradiated on the surface of the resin lens 110 (laser ablation) to roughen the surface 111 (S′3).

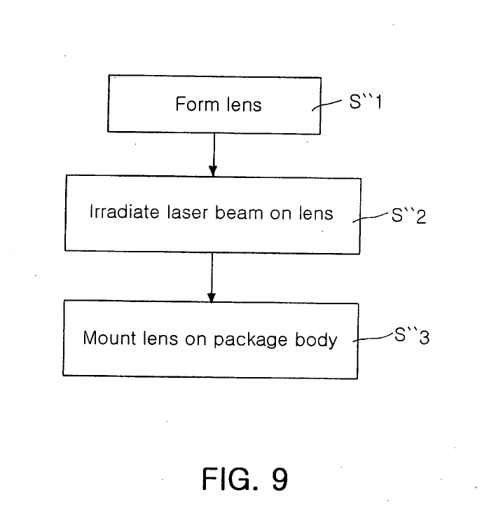

As an alternative to the embodiment shown in FIG. 8, the laser ablation process can be implemented first, and then the lens can be mounted. That is, as shown in FIG. 9, after forming the lens 110 by injection molding, etc. (S″1), the laser beam is irradiated on the surface of the lens 110 to roughen the surface 111(S″2). Then, the lens 110 with the roughened surface thereof is mounted on the package body 101 (S″3).

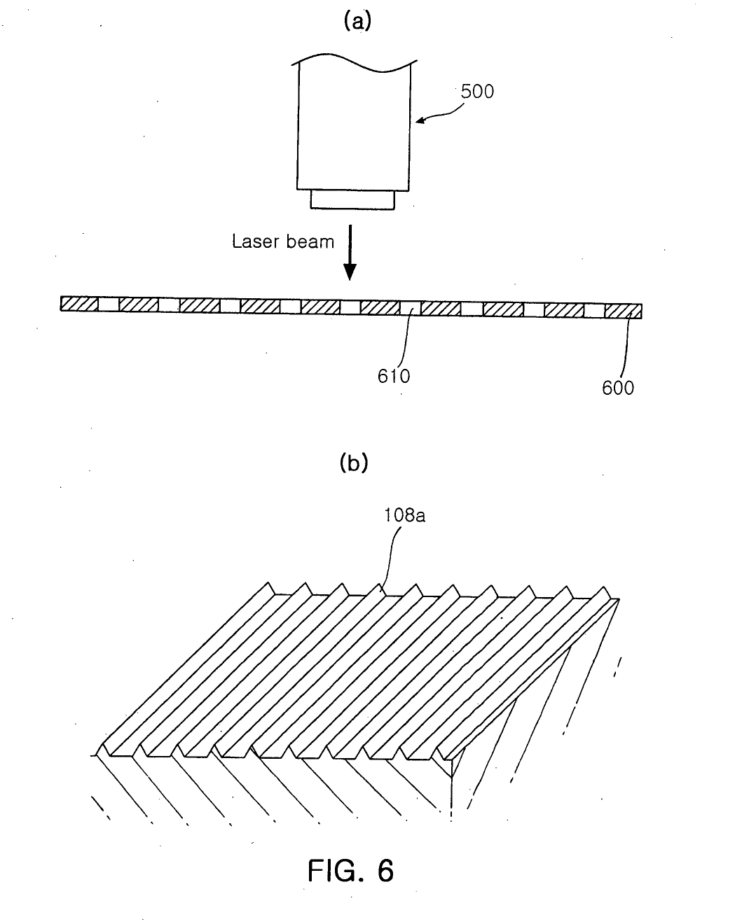

If necessary, a patterned mask can be used to roughen the surface of the light-transmitting resin part (the resin encapsulant or the lens) in a desired regular pattern. For example, as shown in FIG. 6a, the laser ablation process can be implemented with a pattern mask 600 placed between the light-transmitting resin part (the resin encapsulant 107 or the lens 111) and the laser beam irradiator 500. A pattern mask 600 with a plurality of slits can be used to form a regular rough pattern of a plurality of stripes on the surface 108 of the light-transmitting resin part (See FIG. 6b).

### EXAMPLES

The inventors of the present invention conducted laser ablation on the surface of the silicone resin used for the resin encapsulant. The conditions for the laser ablation process were divided into two sets.

First, the LED chip was encapsulated by the silicon resin. Then, the silicone resin was dried and cured at 150° C. Using a KrF 248 nm excimer laser, the laser ablation was conducted under the following two sets of conditions on the cured silicone resin.
(1) Beam power: 500 mJ/cm², beam size: 1 mm×1 mm, repetition frequency: 100 Hz, pulse duration: tens of nanoseconds.
(2) Beam power: 1000 mJ/cm², beam size: 1 mm×1 mm, repetition frequency: 100 Hz, pulse duration: tens of nanoseconds.

Without conducting the laser ablation process, the surface of the cured silicone resin exhibited Average Roughness (Ra) of about 0.6 nm. However, after conducting the laser ablation under the conditions (1), it was confirmed that the surface of the silicone resin exhibited Ra of about 21 nm, and that cone-shaped protrusions of about 100 nm in size are present on the surface of the silicone resin.

After conducting the laser ablation under the conditions (2), it was confirmed that the surface of the silicone resin exhibited Ra of about 85 nm, and that cone-shaped protrusions of about 240 to 270 nm in size are present on the surface of the silicone resin.

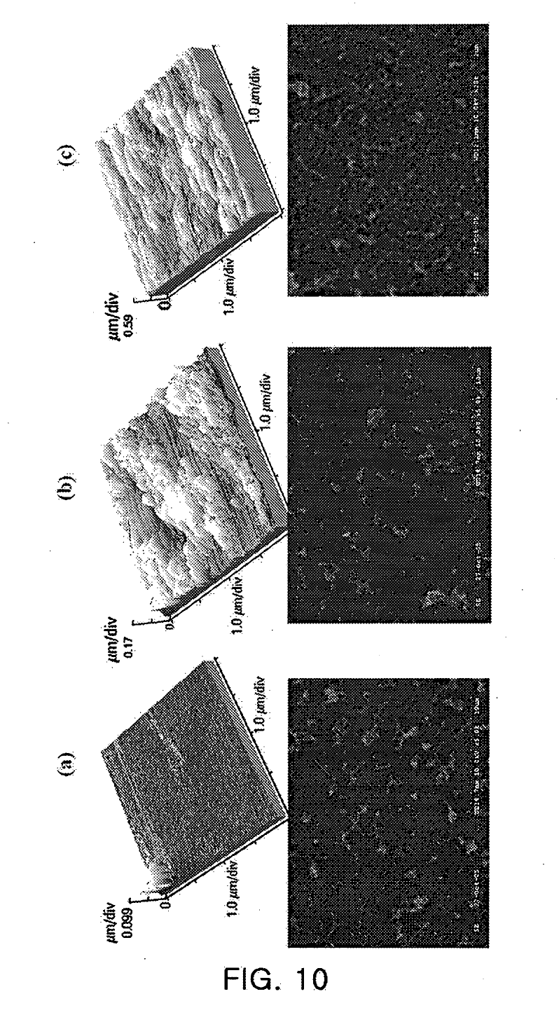

FIG. 10(a) is an AFM image and a SEM picture of a comparative sample without the laser ablation, whereas FIGS. 10(b) and 10(c) are AFM images and SEM pictures of inventive samples with laser ablation conducted under the conditions (1) and (2), respectively. As shown in FIG. 10, the silicone resin sample (FIG. 10(a) without the laser beam irradiated) has a smooth surface, whereas the silicone resin samples (FIG. 10(b) and FIG. 10(c)) have relatively large roughness formed on the surfaces thereof. In particular, comparing the SEM pictures of FIG. 10(b) and FIG. 10(c), difference is clear between the surface with the laser ablation performed at an energy density of 1000 mJ/cm² (FIG. 10(b)) and the surface with the laser ablation performed at an energy density of 500 mJ/cm².

According to the present invention as set forth above, a laser ablation process is used to roughen the surface of a resin encapsulant or a lens, thereby effectively improving the light extraction efficiency of an LED package. Furthermore, the conditions for the laser ablation process can be adjusted to precisely and easily regulate the roughening process, thereby preventing the damage to the resin encapsulant or the lens.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a light emitting diode package comprising:
forming a light-transmitting resin part of a light emitting diode package; and
irradiating a laser beam on a surface of the light transmitting resin part to roughen the surface of the light-transmitting resin part.

2. The method according to claim 1, wherein the light-transmitting resin part comprises a resin encapsulant for encapsulating an LED chip.

3. The method according to claim 2, wherein the step of forming the light-transmitting resin part comprises encapsulating the LED chip with the resin encapsulant and curing the resin encapsulant.

4. The method according to claim 2, wherein the resin encapsulant comprises a silicone resin.

5. The method according to claim 2, wherein the resin encapsulant comprises one selected from the group consisting of polyethylene, polypropylene, polystyrene, polyethylene terephthalate, polyethylene terenaphthalate, polybutylene terephthalate, polyethersulfone, polyetheretherketone, polycarbonate, polyimide, polyetherimide, a cellulose triacetate resin, a polyacrylate resin, a polysulfone resin and a fluoride resin.

6. The method according to claim 1, wherein the step of forming a light-transmitting resin part comprises forming a lens.

7. The method according to claim 6, further comprising mounting the lens on the package body with the LED chip mounted therein between the step of forming a light-transmitting resin part and the step of irradiating a laser beam.

8. The method according to claim 6, further comprising mounting the lens on the package body with the LED chip mounted therein after the step of irradiating the laser beam.

9. The method according to claim 6, wherein the lens comprises a silicone resin or epoxy resin.

10. The method according to claim 1, wherein the step of irradiating the laser beam comprises placing a cover plate, which transmits the laser beam, on the light-transmitting resin part.

11. The method according to claim 1, wherein the step of irradiating the laser beam comprises placing a pattern mask, which selectively transmits the laser beam, on the light-transmitting resin part.

12. The method according to claim 11, wherein the pattern mask has a plurality of slits.

13. The method according to claim 1, wherein the laser beam comprises one selected from the group consisting of a KrF laser beam of a wavelength of 248 nm, an ArF laser beam of a wavelength of 193 nm, a CO₂ gas pulse laser beam and a Nd—YAG pulse laser beam of a wavelength of 355 nm.

14. The method according to claim 1, wherein the light transmitting resin comprises a silicone resin and the laser beam comprises a KrF laser beam having an energy density of 500 to 1000 mJ/cm² and a repetition frequency of 100 Hz.
